(19) United States
(12) Patent Application Publication
(10) Pub. No.: US 2026/0282216 A1
(43) Pub. Date: Sep. 17, 2026

(54) EMBOSSED FOLDOVER ASSEMBLY FOR FLEXIBLE PRINTED ELECTRONIC DEVICE

(71) Applicant: SIMPLE USE SYSTEMS LLC, Twin Lake, MI (US)

(72) Inventor: Jeffrey Malec, Twin Lake, MI (US)

(21) Appl. No.: 19/566,342

(22) Filed: Mar. 13, 2026

Related U.S. Application Data
(60) Provisional application No. 63/771,743, filed on Mar. 14, 2025.

(51) Int. Cl. H05K 1/02

(52) U.S. Cl. CPC H05K 1/028

(57) ABSTRACT

An embossed foldover assembly for a flexible printed electronic device includes a flexible substrate with a base portion and a foldover portion connected along a fold line. An electrical circuit on the base portion includes embossed electrical contacts. The foldover portion folds over the base portion to form a cavity that can retain a battery or receive an actuator or connector component. The embossed contacts on the base portion can engage a corresponding path contact to establish the electrical circuit through mechanical pressure engagement. Various actuator configurations including pull tab, slider, rotary tab, and rotary wheel actuators can control circuit operation. A film connector configuration enables insertable connection of flexible tails without permanent bonding. The conformable construction accommodates curved surfaces and flexing while maintaining reliable electrical contact.

### CROSS-REFERENCE TO RELATED APPLICATIONS

This application claims the benefit of U.S. Provisional Application No. 63/771,743, filed on Mar 14, 2025. The entire disclosure of the above application is incorporated herein by reference.

### FIELD

The present technology relates to a labeling system and switching mechanism, and, more particularly, to a reusable electrical control mechanism for selectively activating an illuminated display element or electronic device.

### INTRODUCTION

This section provides background information related to the present disclosure which is not necessarily prior art.

An illuminated label or display has become increasingly important in product packaging and marketing. Illuminated labels offer enhanced visibility and consumer engagement in retail environments. The illuminated label can rely on basic electrical circuits with simple on/off functionality, powered via a battery. This can limit the versatility and practical application in real-world settings.

The illuminated display system can often employ single-use activation mechanisms, such as a pull tab commonly found in a greeting card and other promotional materials. The single-use mechanism, while functional for its intended purpose of minimizing electrical discharge until a user desires to electrify the display system, creates unnecessary waste and limits the product's utility once activated. The inability to deactivate and reactivate the system can result in premature battery depletion and reduced product longevity. The frustrating inefficiency of the single-use pull tab lies in its one-time activation nature, where a user must carefully time when to pull the tab since there is no way to deactivate the circuit once engaged, leading to unnecessary battery drain and limited product utility.

What is more, the illuminated label technology struggles with conformability to various surface geometries, particularly in beverage and consumer product packaging. The illuminated label technology can utilize rigid components that militate against proper adhesion to a curved surface, resulting in poor aesthetic appearance and compromised functionality. Additionally, the illuminated label technology can lack the ability to adjust illumination intensity to accommodate different ambient lighting conditions, leading to either excessive power consumption or insufficient visibility.

Another challenge to the illuminated label technology is power management. Without effective means to control power consumption, the battery can be quickly depleted, rendering the illuminated feature useless. Furthermore, the illuminated label technology can lack the capability to connect to external power sources, limiting its practical applications and forcing reliance solely on internal battery power which provides limited power capabilities. This is because certain batteries can be constrained by the finite power capacity, which can inevitably deplete and render the illuminate feature non-functional unless the system includes alternative power options.

Accordingly, there is a continuing need for an illuminated label system that can provide reusable activation capabilities, adaptable illumination control, power management features, and flexibility in conforming to various surface geometries while maintaining reliable electrical connections and structural integrity.

### SUMMARY

In concordance with the instant disclosure, an illuminated label system that may provide reusable activation capabilities, adaptable illumination control, power management features, and flexibility in conforming to various surface geometries while maintaining reliable electrical connections and structural integrity, has surprisingly been discovered.

The present technology includes articles of manufacture, systems, and processes that relate to a reusable pull-tab switching mechanism for an illuminated label system featuring selective circuit activation, multi-mode illumination control, and power management capabilities for conformable display elements.

In certain embodiments, a flexible printed electronic assembly is provided. The flexible printed electronic assembly can include a flexible substrate, a pair of first electrical contacts, a path contact, and a securing member. The flexible substrate can include a base portion and a foldover portion. The base portion and the foldover portion can be integrally connected along a fold line. The foldover portion and the base portion can define a cavity therebetween. A printed electrical circuit can be disposed on at least one of the base portion and the foldover portion. The base portion can have a base embossed portion extending above a surface plane of the base portion and the foldover portion can have a foldover embossed portion extending above a surface plane of the foldover portion. The pair of base electrical contacts can be disposed on the base embossed portion of the base portion. The base electrical contacts can be spaced apart from each other on the base portion. The path contact can be received by the cavity formed between the base portion and the foldover portion. The path contact can be in selective electrical communication with the pair of base electrical contacts to complete the printed electrical circuit. The securing member can include a tab and a slot. The tab can be insertable through the slot to secure the foldover portion to the base portion.

In certain embodiments, a flexible printed electronic assembly is provided. The flexible printed electronic assembly can include a flexible substrate, a pair of base electrical contacts, a path contact, a securing member, an actuator, and a retaining member. The flexible substrate can include a base portion and a foldover portion. The base portion and the foldover portion can be integrally connected along a fold line. The foldover portion and the base portion can define a cavity therebetween. A printed electrical circuit can be disposed on the base portion. The base portion can have a base embossed portion extending above a surface plane of the base portion and the foldover portion can have a foldover embossed portion extending above a surface plane of the foldover portion. The pair of base electrical contacts can be disposed on the base embossed portion of the base portion. The base electrical contacts can be spaced apart from each other on the base portion. The path contact can be received by the cavity formed between the base portion and the foldover portion. The path contact can be in selective electrical communication with the pair of base electrical contacts to complete the printed electrical circuit. The securing member can include a tab and a slot. The tab can be insertable through the slot to secure the foldover portion to the base portion. The actuator can move between an activated position and a deactivated position. In the activated position, the path contact can complete the printed electrical circuit with the pair of base electrical contacts and in the deactivated position, the actuator can interrupt the printed electrical circuit. The retaining member can be configured to maintain the actuator between the base portion and the foldover portion while permitting repeated movement between the activated position and the deactivated position.

In certain embodiments, a method of operating a flexible printed electronic assembly is provided. The method can include providing the flexible printed electronic assembly having the pair of base contacts and the path contact. The method can include placing the pair of base contacts in electrical communication with the path contact, whereby an electrical circuit is formed.

In certain embodiments, a method of operating a flexible printed electronic assembly is provided. The method can include providing the flexible printed electronic assembly having the pair of base contacts and the actuator. The method can include placing the pair of base contacts in electrical communication with the actuator, whereby an electrical circuit is formed.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

FIG. 1 is a top plan view of a flexible printed electronic assembly;

FIG. 2 is a side elevational view of the flexible printed electronic assembly folded for operation;

FIG. 3 is a side elevational view of the flexible printed electronic assembly folded for operation and including a battery;

FIG. 4 is a diagram depicting the flexible printed electronic assembly with a battery installed in the flexible printed electronic assembly;

FIG. 5 is a diagram depicting the flexible printed electronic assembly with a standalone battery system coupled to the flexible printed electronic assembly;

FIG. 6 is a side elevational view of the flexible printed electronic assembly folded for operation and including a film connector;

FIG. 7A is a top plan view within the flexible printed electronic assembly wherein a pull tab actuator is shown in a deactivated position;

FIG. 7B is a top plan view within the flexible printed electronic assembly wherein the pull tab actuator is shown in an activated position;

FIG. 8A is a side elevational view within the flexible printed electronic assembly wherein the pull tab actuator is shown in the deactivated position;

FIG. 8B is a side elevational view within the flexible printed electronic assembly wherein the pull tab actuator is shown in the activated position;

FIG. 9A is a top plan view within the flexible printed electronic assembly wherein a slider actuator is shown in the deactivated position;

FIG. 9B is a top plan view within the flexible printed electronic assembly wherein the slider actuator is shown in the activated position;

FIG. 10A is a top plan view within the flexible printed electronic assembly wherein a rotary actuator is shown in the deactivated position;

FIG. 10B is a top plan view within the flexible printed electronic assembly wherein the rotary actuator is shown in the activated position;

FIG. 11A is a top plan view within the flexible printed electronic assembly with multiple electrical circuits wherein the pull tab actuator is shown in the deactivated position;

FIG. 11B is a top plan view within the flexible printed electronic assembly with multiple electrical circuits wherein the pull tab actuator is shown in the activated position resulting in an electrical circuit for generating low brightness;

FIG. 12 is a diagram depicting the flexible printed electronic assembly having a rotary wheel actuator;

FIGS. 13-14 are flowcharts depicting a method of operating the flexible printed electronic assembly; and

FIG. 15 is a top plan view of the flexible printed electronic assembly with the pull tab actuator connected via a perforated edge.

### DETAILED DESCRIPTION

The following description of technology is merely exemplary in nature of the subject matter, manufacture and use of one or more inventions, and is not intended to limit the scope, application, or uses of any specific invention claimed in this application or in such other applications as can be filed claiming priority to this application, or patents issuing therefrom. Regarding methods disclosed, the order of the steps presented is exemplary in nature, and thus, the order of the steps can be different in various embodiments, including where certain steps can be simultaneously performed, unless expressly stated otherwise. “A” and “an” as used herein indicate “at least one” of the item is present; a plurality of such items can be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that can arise from ordinary methods of measuring or using such parameters.

Although the open-ended term “comprising,” as a synonym of non-restrictive terms such as including, containing, or having, is used herein to describe and claim embodiments of the present technology, embodiments can alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that can be recited in the art, even though element D is not explicitly described as being excluded herein.

Disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter can define endpoints for a range of values that can be claimed for the parameter. For example, if Parameter X is exemplified herein to have value A and also exemplified to have value Z, it is envisioned that Parameter X can have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1–10, or 2–9, or 3–8, it is also envisioned that Parameter X can have other ranges of values including 1–9, 1–8, 1–3, 1–2, 2–10, 2–8, 2–3, 3–10, 3–9, and so on.

When an element or layer is referred to as being “on,” “engaged to,” “connected to,” or “coupled to” another element or layer, it can be directly on, engaged, connected or coupled to the other element or layer, or intervening elements or layers can be present. In contrast, when an element is referred to as being “directly on,” “directly engaged to,” “directly connected to” or “directly coupled to” another element or layer, there can be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. can be used herein to describe various elements, components, regions, layers and/or sections, these elements, components, regions, layers and/or sections should not be limited by these terms. These terms can be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, can be used herein for ease of description to describe one element or feature's relationship to another element(s) or feature(s) as illustrated in the figures. Spatially relative terms can be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device can be otherwise oriented (rotated 90 degrees or at other orientations) and the spatially relative descriptors used herein interpreted accordingly.

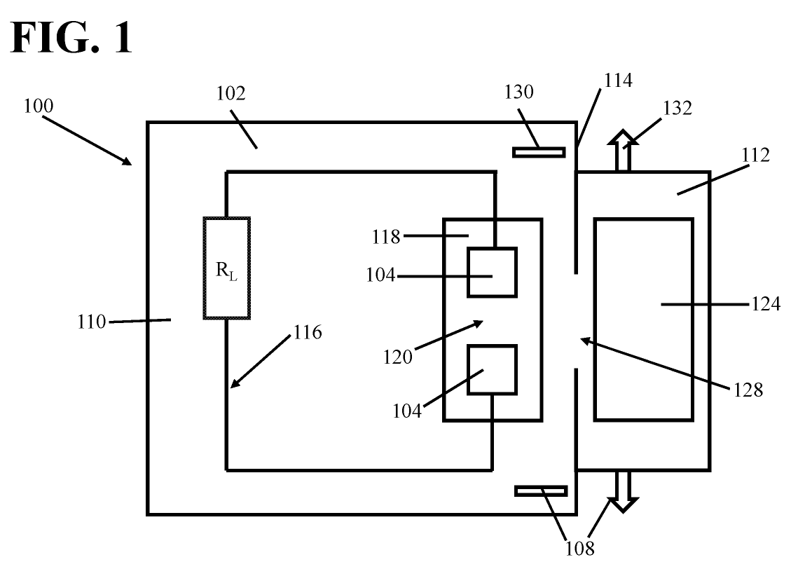

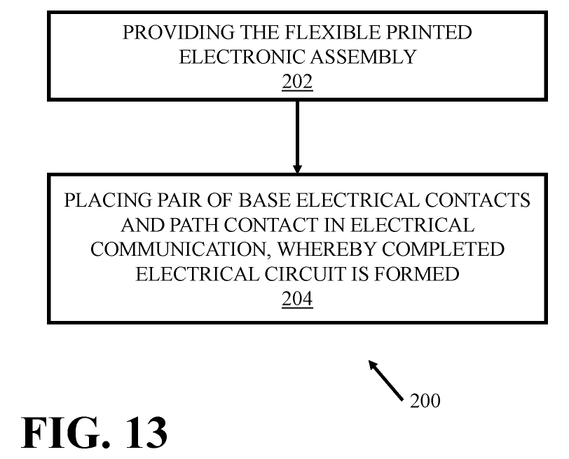

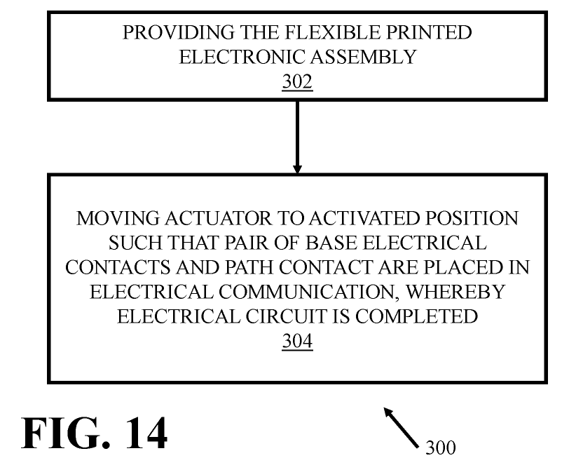

The present disclosure provides a flexible printed electronic assembly 100, shown generally in FIGS. 1-12 and 15 and a method 200, 300 for operating the flexible printed electronic assembly 100, shown generally in FIGS. 13-14. The present disclosure addresses certain challenges by providing a platform manufacturing technology that creates functional electronic components from a flexible substrate through embossed raised contact surfaces that provide mechanical stiffness and reliable electrical contact pressure, foldover construction that forms enclosures and contact arrangements without separate parts, and mechanical tab-and-slot securing. The flexible printed electronic assembly 100 can include a flexible substrate 102, a pair of base electrical contacts 104, a path contact 106, and a securing member 108.

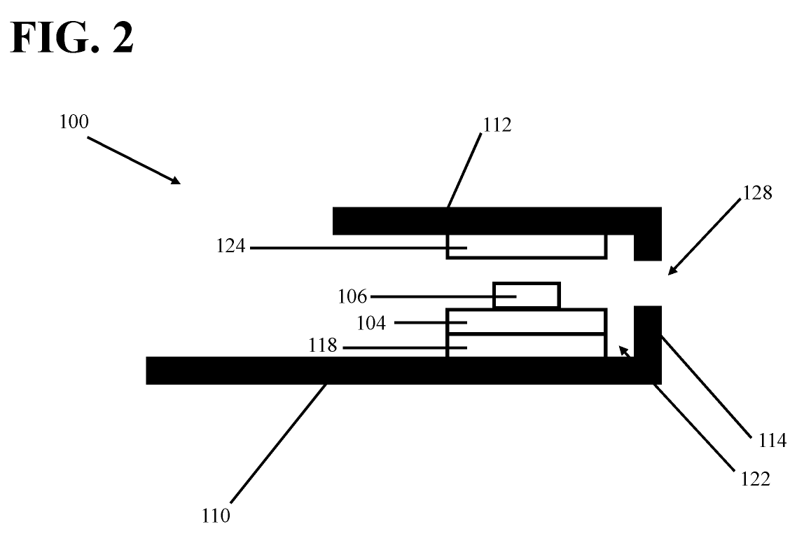

As shown in FIGS. 1-2, the flexible substrate 102 can include a base portion 110 and a foldover portion 112 integrally connected along a fold line 114. The flexible substrate 102 can facilitate printing of an electrical circuit 116 on the base portion 110, as described herein. The flexible substrate 102 can accept multiple printing passes to build up conductive layers, insulating layers, or functional layers. The flexible substrate 102 can be embossed to create a base embossed portion 118 extending above a surface plane of the base portion 110. The base embossed portion 118 can provide increased local stiffness to certain portions of the flexible substrate 102 without cracking, tearing, or losing structural integrity. The flexible substrate 102 can withstand embossing operations while maintaining flexibility in non-embossed areas.

It should be appreciated that the electrical circuit 116 can be formed on the flexible substrate 102 using any suitable printing technique that deposits electrically conductive materials in a predetermined pattern. The electrical circuit 116 can be formed using screen printing, inkjet printing, flexographic printing, gravure printing, offset printing, or other printing methods suitable for depositing conductive materials onto flexible substrates, as desired. The printing process can accommodate multiple print passes to build up a conductive layer thickness for electrical performance. Registration between multiple print layers can be maintained through alignment marks, registration pins, or vision systems integrated into the printing equipment. The printed conductive materials can be cured using thermal curing, ultraviolet curing, infrared curing, or other curing methods appropriate to the ink chemistry and substrate material. Curing parameters can be selected to ensure full development of electrical conductivity while avoiding damage to the substrate or dimensional distortion that would interfere with subsequent embossing or assembly operations.

In addition to printed electronics methods described herein, the electrical circuit 116 can be formed using flexible printed circuit (FPC) technology. FPC implementations can include a polyamide base film with copper etched circuits that define the electrical pathways, contact pads, and circuit traces. The copper circuits can be formed through photolithographic etching processes familiar to those skilled in flexible circuit fabrication. The polyamide base material can provide the necessary flexibility for the foldover operations described herein while the etched copper traces can offer enhanced electrical conductivity compared to printed conductive inks. The embossing operations and foldover construction techniques described throughout this disclosure remain compatible with FPC substrate configurations, with the embossed portions providing localized stiffness to the polyamide-copper laminate structure.

The flexible substrate 102 can be formed from any suitable flexible material capable of receiving a printed circuit and undergoing embossing operations, as described herein. In certain embodiments, the flexible substrate 102 can be formed from polyethylene terephthalate (PET) film, polycarbonate film, polyamide film, polyester film, copper clad film, polyamide (Kapton®) film, sticky vinyl label material, or other flexible polymeric films. Selection of the specific flexible substrate 102 material can be based on factors including flexibility requirements, temperature resistance needed for embossing operations, surface energy for ink adhesion, dimensional stability, cost considerations, and end-use application requirements. A skilled artisan can select a suitable material within the scope of the present disclosure.

While the foregoing disclosure emphasizes a flexible substrate construction, the assembly 100 and associated contact arrangements can also be implemented using rigid circuit board materials. In certain embodiments, the base portion 110 can include a FR4 printed circuit board with the electrical circuit 116, base electrical contacts 104, and associated circuit traces formed through printed circuit board fabrication processes. In such rigid board implementations, the foldover portion 112 need not be integrally connected to the base portion 110 along a fold line 114. Rather, the foldover portion 112 can be a cover element provided as a separate component, whether formed from flexible polymer film, molded plastic, stamped metal, or other suitable materials, that can be secured to the rigid base portion 110 using the securing member 108 or other fastening methods. The embossing principle described herein can be applied to create raised contact surfaces on either the rigid board or the separate cover element, maintaining the concentrated contact pressure and reliable electrical engagement that characterizes the flexible implementations. The rigid board embodiment can retain the reusable actuation functionality and contact pressure advantages while accommodating applications where a rigid substrate is preferred or required.

The flexible substrate 102 can be substantially non-electrically conductive, such that the flexible substrate 102 does not conduct electricity in a manner that would interfere with the electrical circuit 116. The insulating property of the flexible substrate 102 can allow conductive traces to be printed in close proximity without risk of short circuits through the flexible substrate 102 material. The flexible substrate 102 can have sufficient flexibility to conform to non-flat surfaces, contours, curves, and non-planar surfaces such as bottles, packaging, or curved product housings when in use. The flexibility can enable the flexible printed electronic assembly 100 to be applied to or integrated with various product geometries while maintaining electrical functionality.

The flexible substrate 102 can be provided in various thicknesses depending on application requirements. A thinner flexible substrate 102 can provide greater flexibility and conformability to curved surfaces, while a thicker flexible substrate 102 can provide greater structural rigidity and dimensional stability. The substrate thickness can be selected to balance flexibility needs against the mechanical strength required for the particular application and the embossing depth needed to create effective raised contact surfaces. A skilled artisan can select a suitable thickness within the scope of the present disclosure. In certain embodiments, additional flexible substrate layers can be stacked on top of the flexible substrate 102 with spacing materials disposed between the layers to create pockets or cavities. The pockets can be configured to receive and retain the pull tab, house a battery, or accommodate other electronic components such as LEDs, sensors, or integrated circuits. The spacing materials can include a foam layer, an adhesive spacer, or embossed features that define the pocket geometry while maintaining the overall flexible character of the assembly. In certain embodiments, the flexible substrate 102 can be provided with an adhesive backing on one or both sides to enable attachment to products, packaging, or other surfaces. The adhesive backing can be applied to the entire back surface of the flexible substrate 102 or to selected areas only. The adhesive can be pressure-sensitive, heat-activated, or other adhesive types suitable for the end-use application, as desired.

With reference to FIG. 2, the base portion 110 can be formed from the flexible substrate 102 from which the foldover portion 112 extends. The base portion 110 and the foldover portion 112 can be integrally connected, meaning the base portion 110 and the foldover portion 112 can be formed from a single continuous piece of the flexible substrate 102 material rather than being separate pieces that are subsequently joined together. The integral construction can militate against alignment challenges during assembly and can reduce the total number of discrete components requiring handling.

With renewed reference to FIG. 1, the base portion 110 can include the electrical circuit 116 with electrically conductive contacts that define certain circuit pathways for the particular application. The electrical circuit 116 on the base portion 110 can include a contact pad, connection terminal, resistive element, routing trace, crossover insulation, or other circuit components needed for electrical functionality. The electrical circuit 116 on the base portion 110 can be tailored to the specific desired embodiment, whether switch, battery holder, connector, or other functional configuration. The electrical circuit 116 can include the pair of base electrical contacts 104 disposed on the base embossed portion 118 and disposed opposite one another, as shown in FIG. 1. A gap 120 between the base electrical contacts 104 such that the electrical circuit 116 can be interrupted and incomplete with the base electrical contacts 104 alone. By placing the base electrical contacts 104 on the base embossed portion 118, the base electrical contacts 104 can have localized stiffening of the flexible substrate 102 and concentrated contact pressure at engagement points with other electrical contacts.

Returning now to base portion 110 and the foldover portion 112, FIG. 2 depicts the interaction between the base portion 110 and the foldover portion 112 via the fold line 114 to form a cavity 122. In operation, the flexible substrate 102 can be folded along the fold line 114 such that the foldover portion 112 loops over a portion of the base portion 110 to define the cavity 122. The base embossed portion 118 and the base electrical contacts 104 can be disposed within the cavity 122, which in turn can create a localized force between the base electrical contacts 104 and any other contact placed in electrical communication with the base electrical contacts 104 within the cavity 122, as described herein.

In certain alternative construction approaches, the cavity 122 and contact pressure functionality can be achieved using a separately formed foldover portion as a cover component attached to the base portion 110 through adhesive bonding rather than integral foldover construction. The separate cover component can be formed as a discrete piece of flexible substrate material with dimensions corresponding to the foldover portion 112, positioned over the base portion 110, and secured using pressure-sensitive adhesive, heat-activated adhesive, or other bonding methods. A skilled artisan can select a suitable configuration for the flexible printed electronic assembly 100 within the scope of the present disclosure.

As shown in FIG. 2, the foldover portion 112 can include a foldover embossed portion 124 formed similarly to the base embossed portion 118 on the base portion 110. The foldover embossed portion 124 can create a raised contact surface extending above the surface plane of the foldover portion 112 and can be disposed adjacent to the base embossed portion 118 when the foldover portion 112 is folded on the fold line 114 to form the cavity 122. In other words, the base embossed portion 118 and the foldover embossed portion 124 can be disposed opposite one another where the flexible printed electronic assembly 100 is assembled. In this way, the embossed nature of the base embossed portion 118 and the foldover embossed portion 124 can provide concentrated contact pressure at engagement points with other electrical contact points disposed within the cavity, such as the path contact 106.

In certain embodiments, the foldover portion 112 can be formed as a split cover configuration including a front cover section and a rear cover section to provide differential contact pressure and tactile feedback during actuator movement. The rear cover section can be positioned above the path contact 106 when the actuator 146 is in the deactivated position and can be formed from a thinner material thickness than the front cover section, allowing the actuator 146 to move with reduced resistance in the deactivated region. The front cover section can be formed from a thicker material that provides increased stiffness and is positioned to overlay the base electrical contacts 104 in the activated position. As the actuator 146 moves from the deactivated position to the activated position, the path contact 106 can transition from beneath the thinner rear cover section to beneath the thicker front cover section, where the combined thickness of the thicker front cover section and the thinner rear cover section creates increased downward pressure on the path contact 106 and the base electrical contacts 104. The transition between cover sections can create a tactile detent sensation that provides user feedback indicating the actuator 146 has reached the activated position, while the increased pressure in the activated position militates against unintended disconnection and enhances contact reliability. Movement from the activated position back to the deactivated position can similarly provide tactile feedback through the release of pressure as the path contact 106 exits the thicker front cover section.

The path contact 106 can be separately formed from the flexible substrate 102 and can be received by the cavity 122 formed between the base portion 110 and the foldover portion 112. The path contact 106 can be in electrical communication with the pair of base electrical contacts 104 to complete the printed electrical circuit 116. It should be appreciated that the concentrated contact pressure created by the base embossed portion 118 and the foldover embossed portion 124 can hold the path contact 106 in place adjacent the base electrical contacts 104 within the cavity 122. As described herein, non-limiting examples of the path contact 106 can include a non-actuator contact such as a battery, a coin cell battery, a secondary circuit tail from another printed electronic assembly, an external battery assembly tail, flat cell battery tabs, or any component having flat electrical contact tabs or an actuator 126 such as a pull tab, a slider tab, a rotary tab, a rotary wheel or disc, a tear-off tab.

Turning now to the fold line 114 of the flexible substrate 102, which can facilitate the interaction between the base portion 110 and the foldover portion 112. The flexible substrate 102 can be pre-scored along the fold line 114 to facilitate clean, repeatable folding during assembly operation. Pre-scoring of the fold line 114 can be accomplished through die cutting, laser scoring, mechanical scoring, or a perforation pattern that reduces material thickness along the fold line 114 while maintaining sufficient material integrity to keep the base portion 110 and foldover portion 112 as a single integral piece. The fold line 114 can allow the substrate to fold at an intended location without wrinkling, buckling, or creating uncontrolled stress concentrations that could damage printed circuits. Furthermore, it should be understood that two or more fold lines can be provide to provide a vertical portion in the flexible substrate 102 extending between the base portion 110 and the foldover portion 112.

When the foldover portion 112 is folded over the base portion 110, the fold line 114 can include an opening 128 to permit access to the cavity 122 and the base electrical contacts 104. In certain embodiments, the path contact 106 can be placed within the cavity 122 or removed from the cavity 122 via the opening 128, allowing for actuatable switching or removable insertion. For example, the pull tab, slider tab, or rotary tab can be coupled to the path contact 106 and can be inserted through the opening 128 to contact the pair of base electrical contacts 104, while in other embodiments, components such as coin cell batteries, external battery assembly tails, or circuit tails from other printed electronic assemblies can be inserted through the opening 128 to establish electrical communication with the pair of base electrical contacts 104.

With renewed reference to FIG. 1, the flexible printed electronic assembly 100 can include the securing member 108 which can secure the base portion 110 and the foldover portion 112 together along the fold line 114 for operation. The securing member 108 can include a slot 130 and a tab 132. The base portion 110 can include one or more the slots 130 of the securing member 108, each of the slots 130 positioned to receive one of the tabs 132 of the securing member 108 from the foldover portion 112 for mechanical securing of the flexible printed electronic assembly 100 in the folded position. The slot 130 can be formed through die cutting, laser cutting, or other precision cutting methods. The slot 130 can be positioned on any side of the base portion 110 other than the side that includes the fold line 114 to allow the foldover portion 112 to be folded onto the base portion 110. The slot 130 can be sized to provide appropriate clearance for insertion of the tab 132 while maintaining sufficient retention force to hold the base portion 110 and the foldover portion 112 together. It should be understood that other appropriate securing members 108, such as adhesives, can be used to mechanically or otherwise secure the flexible printed electronic assembly 100 in the folded position.

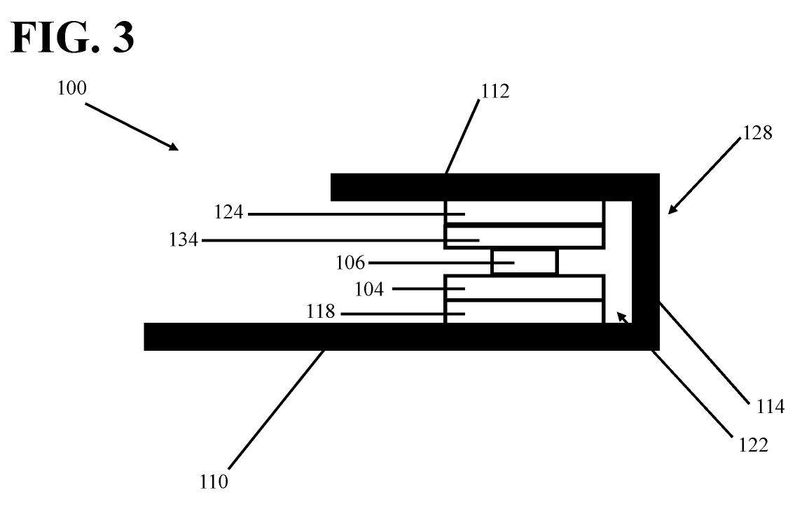

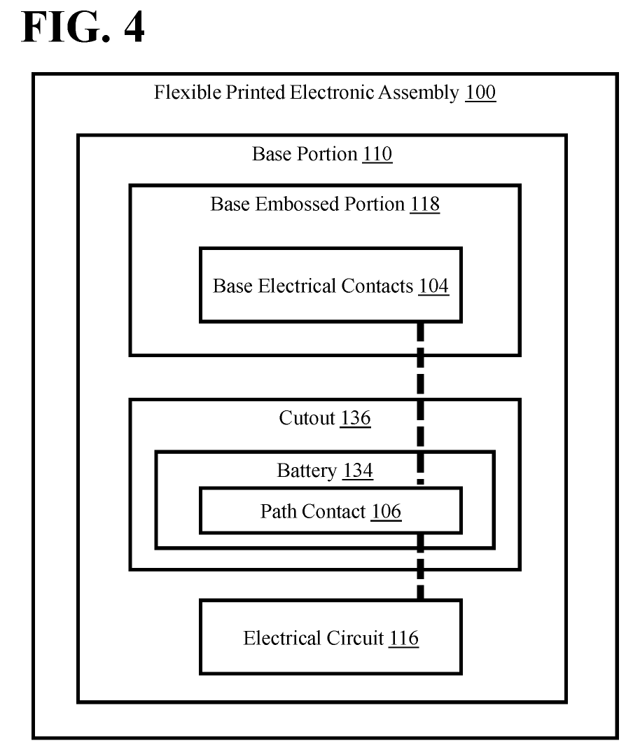

In certain embodiments shown in FIGS. 3-4, the flexible printed electronic assembly 100 can be configured as a battery holder wherein the path contact 106 is a part of or is coupled to a battery 134. The cavity 122 can be formed by folding the foldover portion 112 over the base portion 110 along the fold line 114, with the foldover portion 112 being cut and scored to create a battery pouch. The base electrical contacts 104 of the base portion 110 can contact the path contact 106 in the form of a battery terminal, providing rigidity and electrical connection with the battery 134. The foldover embossed portion 124 of the foldover portion 112 can be positioned to ensure contact pressure on the top of the battery 134 to assist with holding the battery 134, and therefore, the path contact 106 in contact with the base electrical contacts 104 to complete the electrical circuit 116. When the battery 134 is placed within the cavity 122, the negative and positive terminals of the battery 134 can directly contact the pair of base electrical contacts 104 on the base embossed portion 118, thereby completing the printed electrical circuit 116. The foldover portion 112 can be secured to the base portion 110 using the securing member 108, wherein the tab 132 can insert into the slot 130 to hold the battery 134 in place within the cavity 122 and maintain contact pressure between the battery terminals and the pair of base electrical contacts 104. The battery holder configuration can accommodate a single battery 134 or more than one battery 134 arranged in series or parallel configurations, as desired. A skilled artisan can select a suitable battery configuration within the scope of the present disclosure.

In an alternative battery holder embodiment, the base electrical contacts 104 can be positioned to engage opposing surfaces of the battery 134. In such configurations, a first base electrical contact 104 can be disposed on the base portion 110 to contact a first terminal surface (e.g., the bottom) of the battery 134, while another contact can be formed on or integrated with the foldover portion 112 to contact a second terminal surface (e.g., the top) of the battery 134. For coin cell batteries where the negative terminal is on the bottom surface and the positive terminal is on the top surface, the electrical circuit 116 can route one circuit trace to the base electrical contact 104 on the base portion 110 and route a second circuit trace through the fold line 114 to a contact pad on the foldover portion 112. The foldover embossed portion 124 can be positioned to provide dual functionality both ensuring physical contact pressure to retain the battery 134 within the cavity 122 while simultaneously maintaining electrical connection between the top surface of the battery 134 and the contact pad on the foldover portion 112. The opposing-contact configuration allows the battery holder to accommodate various battery form factors and terminal arrangements while maintaining the reliable pressure contact and reusable assembly characteristics of the pull tab switch assembly.

In certain embodiments, the base portion 110 or the foldover portion 112 can include a cutout 136 configured to receive and position the battery 134 within the cavity 122. The dimensions of the cutout 136 can be sized to accommodate specific battery geometries such as coin cells or other battery types, for example. The cutout 136 can be disposed adjacent the base electrical contacts 104 and the path contact 106 to allow for electrical contact between the base electrical contacts 104 and the battery 134 where the battery is installed in the flexible printed electronic assembly 100.

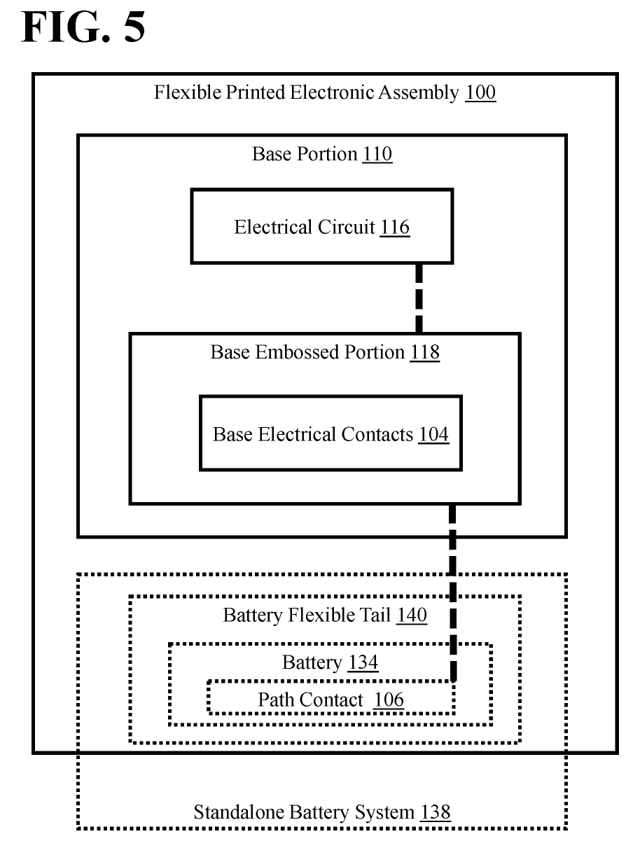

In certain embodiments and as shown in FIG. 5, the flexible printed electronic assembly 100 can be in electrical communication with a standalone battery system 138 that operates independently from the flexible printed electronic assembly 100. The battery system 138 can utilize the same foldover configuration as described herein and be coupled to the electrical circuit 116 of the flexible substrate 102 via a battery flexible tail 140 that extends from the standalone battery system 138 and terminates as the path contact 106 that can be placed in electrical communication with the base electrical contacts 104. Advantageously, utilizing the standalone battery system 138 with the flexible printed electronic assembly 100 can facilitate remote battery location applications, such as positioning the standalone battery system 138 under a bottle or in other locations separated from the flexible printed electronic assembly 100. Further, the separate standalone battery system 138, such as a rechargeable battery 134, can provide the option to make the battery 134 user-replaceable by positioning the standalone battery system 138 in an accessible location. The separate standalone battery system 138 can accommodate either flat or stacked battery arrangements depending on the spatial requirements of the remote mounting location.

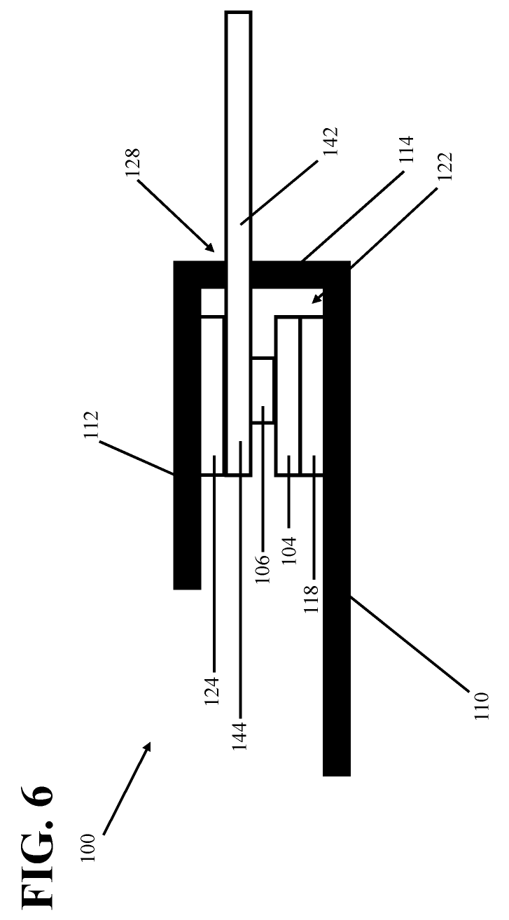

With reference to FIG. 6, the flexible printed electronic assembly 100 can be implemented as part of a larger electrical system utilizing a connector, such as a film connector 142 as the path contact 106 to electrically couple the flexible printed electronic assembly 100 to other electrical components. The film connector 142 can include a control circuit, a sensor input, a power source, and combinations thereof, for example. It should be appreciated that the film connector 142 can be an extension of the flexible printed electronic assembly 100 to create a plug-in electrical connection in the flexible format of the flexible substrate 102. The film connector 142 can function similarly to a card edge connector by utilizing a socket with a spring-loaded contact that grips an edge of a flexible substrate 102 when the film connector 142 is slid into the socket or zero insertion force (ZIF) connector, which uses a mechanical lever that starts in an open position allowing the film connector 142 to be inserted into the flexible substrate 102 without resistance and closes to apply clamping pressure that holds the film connector 142 in place and establishes electrical contact. The film connector 142 can apply the same principle implemented into use with the flexible substrate 102. The removable connection capability of the film connector 142 allows for the electrical extension to occur without the use of a permanent adhesive connection by allowing the film connector 142 to be inserted, removed, and replaced without damaging the flexible substrate 102 or requiring chemical adhesives that can bleed into the base electrical contacts 104 and compromise electrical performance. In this way, the film connector 142 enables a modular assembly approach.

As shown in FIG. 6, the film connector 142 can be electrically coupled to the flexible substrate 102 via the cavity 122 formed during the foldover of the foldover portion 112 onto the base portion 110. The cavity 122 can be configured to receive a connector flexible tail 144 including the path contact 106, positioned to align with the path contact 106. It should be appreciated that the connector flexible tail 144 can be received into the cavity 122 via the opening 128 disposed along the fold line 114 of the flexible substrate 102. The opening 128 can be sized and shaped to receive the film connector 142. Where the connector flexible tail 144 is inserted into the cavity 122, the base embossed portion 118 and the foldover embossed portion 124 can apply compressive forces to the connector flexible tail 144 and the path contact 106from opposing directions, creating an electrical connection between the film connector 142 and the flexible printed electronic assembly 100. The engagement between the path contact 106 of the connector flexible tail 144 and the base electrical contacts 104 can establish the electrical circuit 116 that enables power transfer, signal transmission, or data communication between the film connector 142 and the flexible printed electronic assembly 100 without requiring conductive adhesive or soldering.

In operation, the film connector 142 can accommodate various categories of applications including component connection. The film connector 142 can enable connection of a control circuit, a sensor input, and other power sources that are constructed as separate insertable circuit modules with a connector flexible tail 144. The film connector 142 can further accommodate any device with flat contact surfaces positioned on a connector flexible tail 144 provided the contact geometry is compatible with the cavity 122 of the flexible printed electronic assembly 100 and the device can be configured as an insertable circuit element with the connector flexible tail 144. The connectivity flexibility can enable standardized interface possibilities where different insertable circuit elements can be constructed with compatible connector flexible tail 144 geometry, allowing interchangeable modules to connect to the flexible printed electronic assembly 100.

In certain embodiments, the connector flexible tail 144 can include a retention feature configured to secure the film connector 142 within the cavity 122 and militate against unintended disconnection. The retention feature can provide controlled resistance to removal forces while permitting intentional disconnection when desired by the user, allowing the film connector 142 to maintain reliable electrical contact during normal operation while remaining removable for maintenance or replacement.

The connector flexible tail 144 can include an asymmetric retention feature disposed on a surface of the connector flexible tail 144 that creates differential insertion and removal forces. The asymmetric retention feature can include additional material, an embossed bump, or a protrusion extending from the front edge of the connector flexible tail 144 configured with a gradual insertion profile and a more abrupt retention profile. During insertion into the cavity 122, the asymmetric retention feature can compress or deflect with relatively low insertion force, but once fully inserted, the asymmetric retention feature can engage with the foldover portion 112, base portion 110, or opening 128 to create a retention interface that requires greater removal force to extract the connector flexible tail 144 from the cavity 122, thereby securing the film connector 142 against inadvertent removal.

In certain embodiments, the connector flexible tail 144 can include a latch retention feature configured to mechanically lock the film connector 142 within the cavity 122. The latch retention feature can include a tab-shaped extension or ear-shaped protrusion disposed on one or both lateral edges of the connector flexible tail 144 that passes through the opening 128 during insertion and engages with the foldover portion 112, base portion 110, or edges of the opening 128 to create a mechanical interlock. To disconnect the film connector 142, the user can manipulate the latch retention feature by lifting, squeezing, or deflecting the latch retention feature to disengage the mechanical interlock, allowing the connector flexible tail 144 to be withdrawn from the cavity 122. The latch retention feature can be formed from the same flexible substrate 102 material through die cutting, embossing, or lamination processes, maintaining the thin-film construction without requiring separate retention hardware.

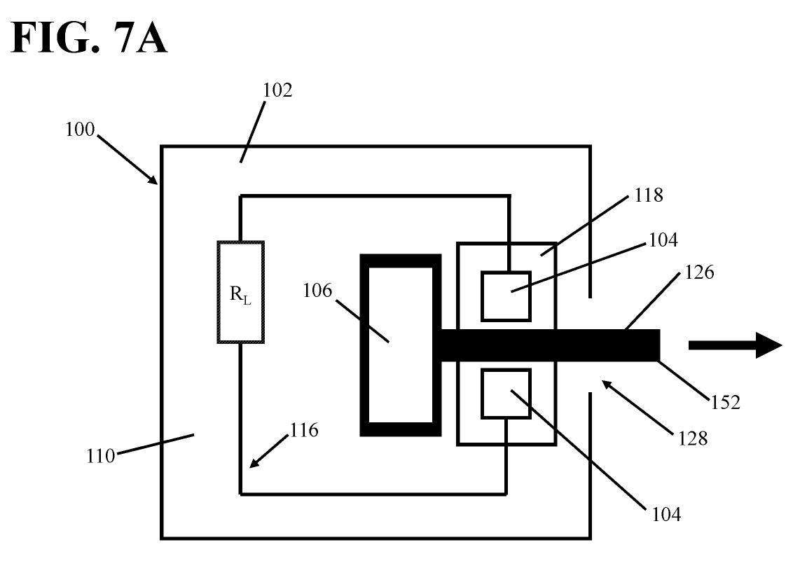

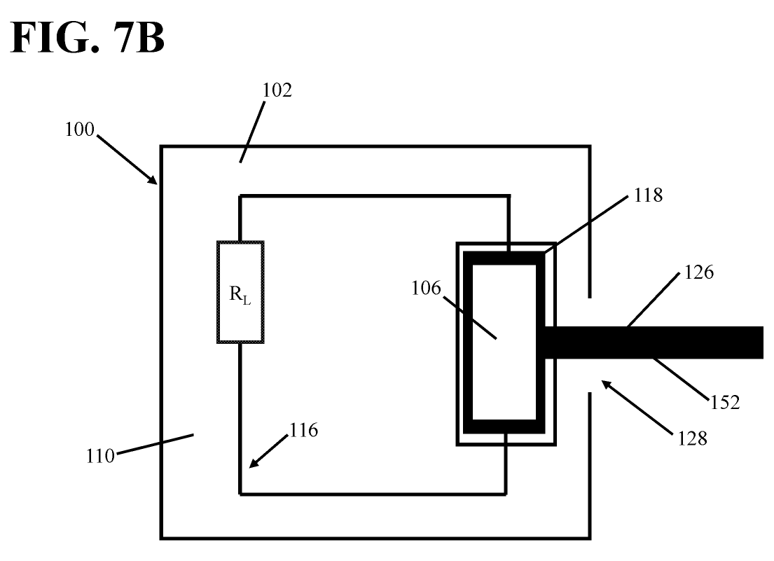

In certain embodiments, the assembly 100 can include electrical switching functionality, which can be achieved through movement of the actuator 126 coupled to the path contact 106 relative to the base electrical contacts 104 on the base portion 110. The actuator 126 can be configured for repeated movement relative to the base portion 110 between a deactivated position, shown in FIGS. 7A, 8A, 9A, 10A, and 11A, and an activated position, shown in FIGS. 7B, 8B, 9B, 10B, and 11B. The actuator 126 can extend beyond the perimeter of the flexible substrate 102 to allow for the user to easily activate the actuator 126. In certain embodiments, the actuator 126 can be disposed through the opening 128. The actuator 126 can take multiple forms including a pull tab that moves in an in/out motion perpendicular to the base film surface, a slider tab that translates in an up/down motion parallel to the base film surface, a rotary tab that pivots around a fixed point, or a rotary wheel that rotates about a central axis, each described herein. A skilled artisan can select a suitable actuator type within the scope of the present disclosure.

In the activated position, the actuator 126 can complete the electrical circuit 116 by positioning the path contact 106 in electrical and conductive communication with the base electrical contacts 104 of the base portion 110. In the deactivated position, the actuator 126 can interrupt the electrical circuit 116 by moving the path contact 106 out of alignment with the base electrical contacts 104, thereby opening the circuit and militating against current flow. It should be appreciated that movement between the activated position and the deactivated position can be repeated as many times as required by the user. The repeated movement capability between the activated position and the deactivated position allows the user to cycle the flexible printed electronic assembly 100 on and off multiple times, providing reusable functionality rather than single-use activation.

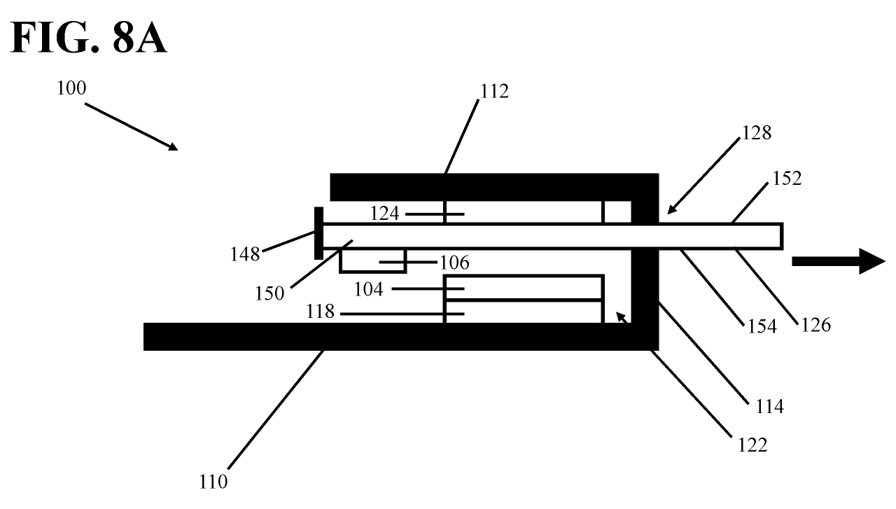

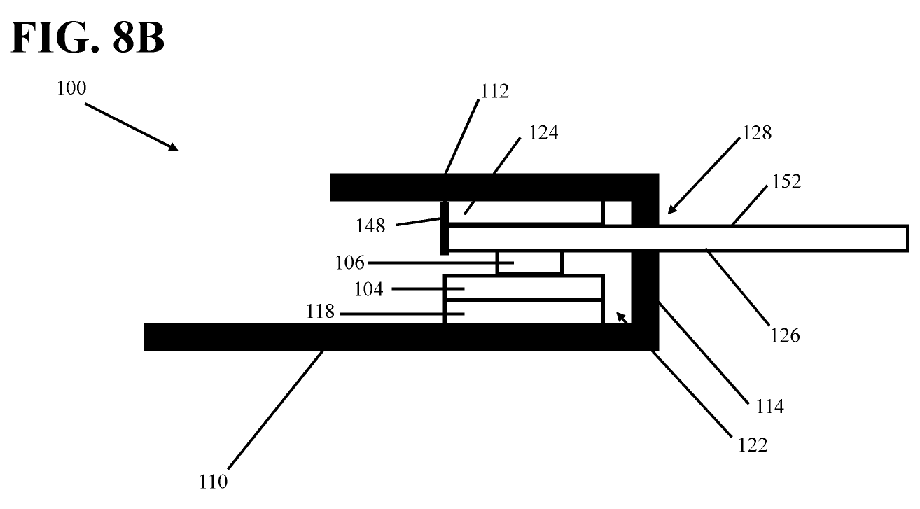

As shown in FIG. 8A and 8B, the flexible printed electronic assembly 100 can further include a retaining member 148 configured to maintain the actuator 126 within the flexible printed electronic assembly 100 while permitting repeated movement between the activated position and the deactivated position. The retaining member 148 can be integrated into either the base portion 110 or the foldover portion 112 and can include a ridge or enlarged feature on an end portion 150 of the actuator 126 that abuts against the foldover portion 112 or other structural element when the actuator 126 reaches a maximum travel position, militating against complete withdrawal of the actuator 126 from the flexible printed electronic assembly 100.

In certain embodiments, the actuator 126 can include an external actuator component or can be mechanically coupled to an external actuator component configured to provide enhanced user interface characteristics while maintaining the switching functionality of the path contact 106 and base electrical contacts 104. The external actuator component can include a larger physical actuator body dimensioned to be more easily graspable by a user than the actuator 126 alone, with the external component mechanically linked to the actuator 126 such that user manipulation of the external actuator component translates into corresponding movement of the actuator 126. The configuration enables the flexible printed electronic assembly 100 to maintain the compact, thin-film construction of the integrated switch mechanism while accommodating applications requiring larger, more robust user interface elements.

In certain embodiments, the external actuator component can be configured for integration with a bezel or housing structure, allowing the switching functionality of the flexible printed electronic assembly 100 to be incorporated into packaged devices or finished products. The external actuator component can include a plastic piece, molded component, or machined part that embeds into, mounts to, or otherwise mechanically integrates with the bezel, providing structural support and aesthetic finishing while maintaining electrical switching capability. The actuator 126 can include a receptacle, snap feature, adhesive bonding surface, or mechanical interlock that secures the external actuator component to the actuator 126 where the external actuator component and the actuator 126 are not co-formed. In operation, when the user manipulates the external actuator component by pushing, pulling, sliding, or rotating depending on the actuator type, the motion can be transferred to the actuator 126, which in turn moves the path contact 106 relative to the base electrical contacts 104 to complete or interrupt the electrical circuit 116. The bezel integration capability allows the flexible printed electronic assembly 100 to function as an embedded switch in finished products where the thin-film assembly is concealed within the product housing while the external actuator component provides the visible and accessible user interface.

The external actuator component can include a mechanical stop configured to limit the range of motion of the actuator 126 and militate against mechanical stress to components of the flexible printed electronic assembly 100. The mechanical stop can be positioned on the external actuator component, on the bezel, or at the interface between the external actuator component and the actuator 126 to define maximum travel limits in both activation and deactivation directions. Where aggressive user force is applied to the external actuator component beyond the intended travel distance required for electrical switching, the mechanical stops can engage to militate against further motion, thereby protecting the actuator 126, the path contact 106, the retaining member 148, and other components of the flexible printed electronic assembly 100 from excessive mechanical stress that could cause tearing, deformation, or failure. The mechanical stop can take the form of protrusions, ridges, walls, or interference features that physically block continued motion when the actuator 126 reaches the intended limit of travel. In this way, the mechanical stop allows the external actuator component to absorb forces from aggressive actuation that might otherwise damage the thin, flexible components of the actuator 126.

With reference to FIGS. 7A-8B, the actuator 126 can include a pull tab actuator 152, where the pull tab actuator 152 extends outward from the electrical circuit 116 via the opening 128 on the electrical circuit 116 and retracts inward to control the electrical circuit 116. The base electrical contacts 104 can be arranged in a linear pattern, while an underside 154 of the pull tab actuator 152 can include the path contact 106. Where the user pulls the pull tab actuator 152 to the activated position, the path contact 106 can align with the base electrical contacts 104 on the base portion 110, completing the electrical circuit 116 and allowing current to flow. Pushing the pull tab actuator 152 to the deactivated position can move the path contact 106 out of contact with the base electrical contacts 104 on the base portion 110, opening the circuit and interrupting current flow. The pull tab actuator 152 can extend through the opening 128, providing a guide that maintains alignment of the pull tab actuator 152 relative to the base electrical contacts 104 throughout the range of motion. The motion of the pull tab actuator 152 can provide intuitive operation where pulling activates illumination and pushing deactivates it, enabling the reusable functionality.

In certain embodiments, the pull tab actuator 152 can include an alignment extension configured to militate against lateral tilting or offset of the pull tab actuator 152 during movement between the activated position and the deactivated position. The alignment extension can extend from a body of the pull tab actuator 152 into a corresponding alignment channel formed in the base portion 110, the foldover portion 112, or both. The alignment channel can be created by removing a portion of material or adhesive from the flexible printed electronic assembly 100 behind the pull tab actuator 152 travel path, providing clearance for the alignment extension to slide within. The alignment extension and alignment channel interaction can constrain lateral movement of the pull tab actuator 152, maintaining alignment of the path contact 106 with the base electrical contacts 104 throughout the range of motion and militating against the pull tab actuator 152 from cutting into adhesive materials or stressing attachment points. In alternative embodiments, the pull tab actuator 152 can be formed with increased width in the region carrying the path contact 106, providing greater lateral stability through increased contact area with the opening 128 and cavity 122 surfaces, though such wider configurations may require additional clearance space behind the flexible printed electronic assembly 100 to accommodate the extended pull tab actuator 152 dimensions.

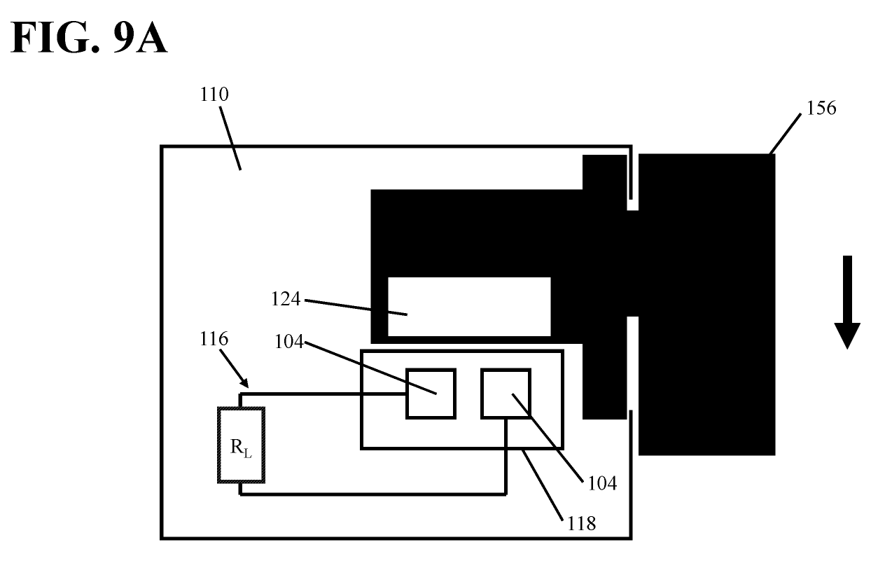

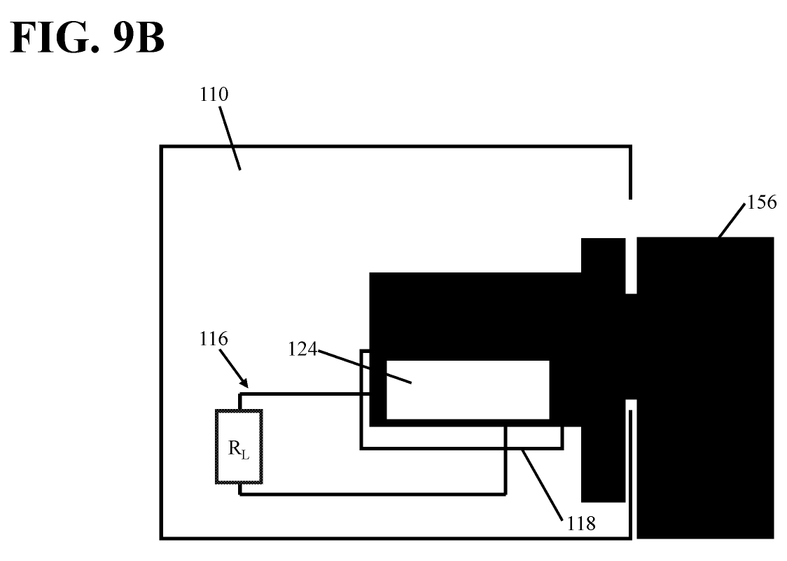

With reference to FIGS. 9A-9B, the actuator 126 can include a slider actuator 156 configured to allow for the electrical circuit 116 to be completed via translational motion parallel to the flexible printed electronic assembly 100 rather than perpendicular to the flexible printed electronic assembly 100 as shown in the pull tab actuator 152 configuration. One or more path contact 106 can be arranged in a linear array extending along the direction of slider actuator 156 travel, such that when in the activated position, the path contact 106 contacts the base electrical contacts 104. The opening 128 in the fold line 114 can be elongated to accommodate the extended travel path of the slider actuator 156 as the slider actuator 156 translates parallel relative to the flexible printed electronic assembly 100.

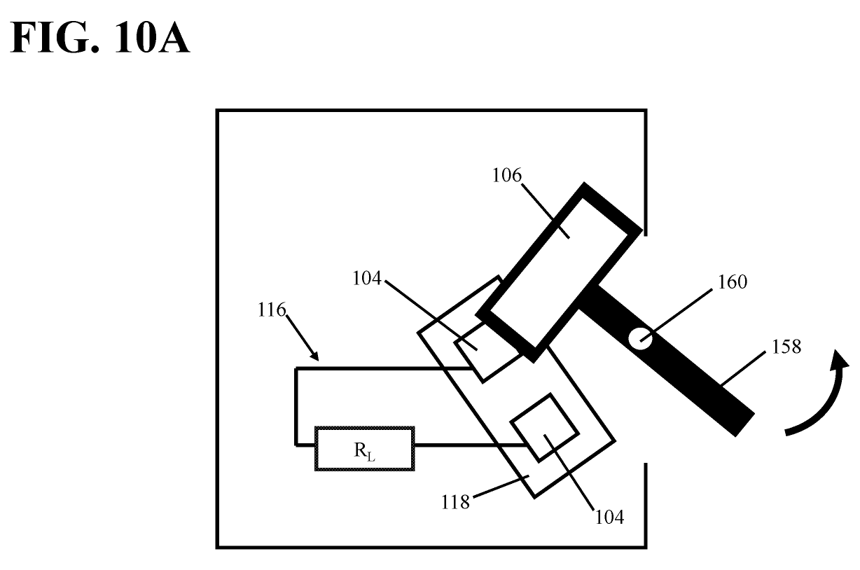

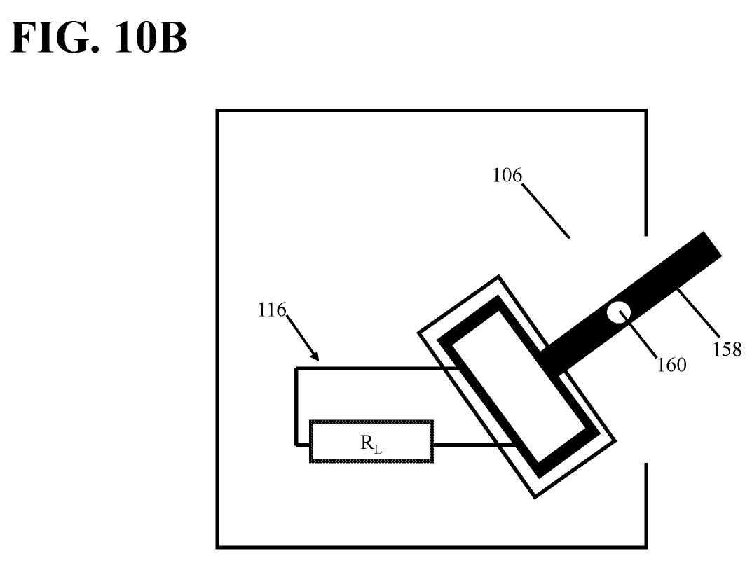

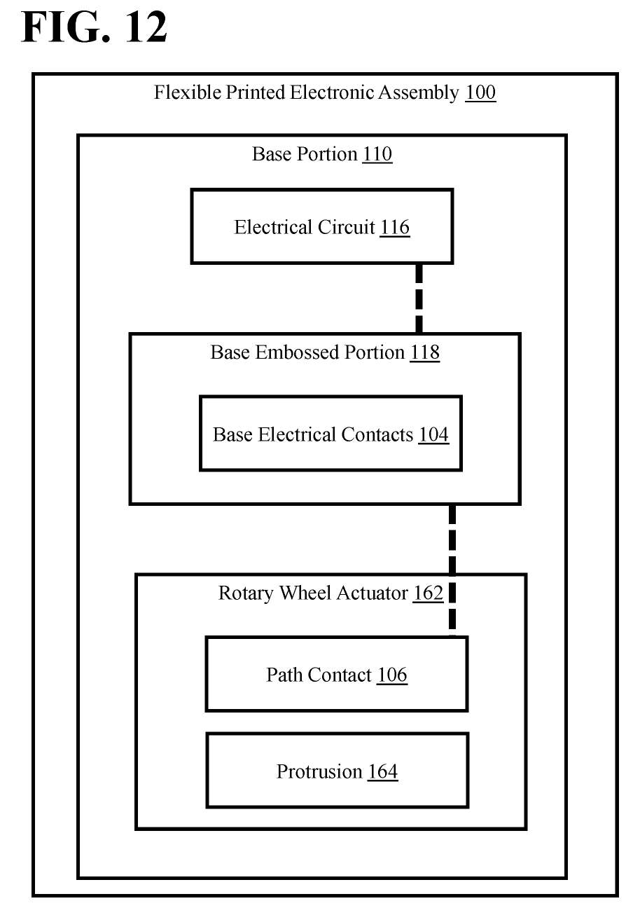

With reference to FIGS. 10A-10B, the actuator 126 can include a rotary tab actuator 158 configured to allow for the electrical circuit 116 to be completed via a pivoting motion. The rotary tab actuator 158 can utilize a fixed attachment point 160 to achieve switching functionality through angular displacement. The rotary tab actuator 158 can be affixed to the base portion 110 through a pivot mechanism at the fixed attachment point 160 to allow the rotary tab actuator 158 to rotate. The path contact 106 disposed on the rotary tab actuator 158 can contact the base electrical contacts 104 when in the activated position to complete the electrical circuit 116. When the user rotates the rotary tab actuator 158 from the deactivated position to the activated position, the path contact 106 can sweep across the arc of the rotary tab actuator 158 and come into contact with the corresponding base electrical contacts 104 on the base portion 110, completing the circuit. Rotation in the opposite direction can move the path contact 106 out of alignment with the base electrical contacts 104, opening the circuit and disconnecting the electrical circuit 116. The rotary tab actuator 158 can be implemented as a rotary wheel actuator 162 by employing a full circular disc as the actuator element rather than an extended tab. With reference to FIG. 12, the rotary wheel actuator 162 can include one or more protrusions 164 extending from a perimeter of the rotary wheel actuator 162 that engage with the fold line 114 to limit the rotational range of the rotary wheel actuator 162 and militate against the path contact 106 from exiting the flexible printed electronic assembly 100.

It should be appreciated that the actuator 126 and other components of the flexible printed electronic assembly 100 can be fabricated as integral extensions of the base portion 110 rather than as separate parts requiring independent handling and assembly. These integrated components can remain attached to the flexible substrate 102 during the printing and embossing manufacturing processes, sharing the same substrate material and undergoing simultaneous processing with the circuit features including the base electrical contacts 104, the path contact 106 and the electrical circuit 116. Perforation patterns, such as the fold line 114 can be formed in the flexible substrate 102 at predetermined locations to define the boundaries between the base portion 110 and the components intended for subsequent manipulation or insertion, such as the foldover portion 112 along the fold line 114. As an example, the pull tab actuator 152 can be fabricated as an extension of the flexible substrate 102 with perforations defining an outline of the pull tab actuator 152. During assembly, the pull tab actuator 152 can be pulled apart from the flexible substrate 102 at the perforation and inserted through the opening 128 in the fold line 114 such that the path contact 106 and the base electrical contacts 104 align during use.

With reference to FIG. 12, the actuator 126 can be configured to connect to multiple electrical circuits 116 rather than just turning one electrical circuit 116 on and off. Instead of a single pair of contacts, such as the base electrical contacts 104, the base portion 110 can include multiple separate pairs of base electrical contacts 104 arranged along a path of travel of the path contact 106. As the actuator 126 moves to different positions, the path contact 106 can contact to different pairs of base electrical contacts 104, routing power to different circuits. In this way, the path contact 106 works like a selector switch where moving the actuator 126 changes which circuit is active.

It should be appreciated that the flexible printed electronic assembly 100 can include multiple switch assemblies configured to control separate electrical circuits 116 independently. The base portion 110 can include a set of base electrical contacts 104 and another set of base electrical contacts 104, each pair associated with a distinct electrical circuit 116. A first actuator 126 coupled to a first path contact 106 can selectively complete a first electrical circuit 116, while a second actuator 126 coupled to a second path contact 106 can selectively complete a second electrical circuit 116. The multiple switch configuration can enable the flexible printed electronic assembly 100 to provide multi-function control within a single integrated assembly, allowing independent activation and deactivation of separate circuits without requiring multiple discrete switch components.

The multiple switch configuration can be implemented to control lighting characteristics in applications where variable color temperature is desired. The first electrical circuit 116 can power a first set of light emitting diodes (LEDs) with warm color temperature characteristics, while another electrical circuit 116 can power a second set of LEDs with cool color temperature characteristics. The actuator 126 and another actuator 126 can be operated independently to activate the warm LEDs only, the cool LEDs only, or both LED sets simultaneously. Where both circuits are activated, the warm and cool LEDs can produce mixed color temperature output. Where either or both actuator 126 configurations include variable positioning as described herein for brightness control, the user can adjust the relative intensities of the warm and cool LED sets to create a continuously adjustable color temperature range. For example, positioning the actuator 126 at high intensity while positioning the another actuator 126 at low intensity produces a predominantly warm color temperature, while reversing these positions produces a predominantly cool color temperature, with balanced positioning producing neutral white light.

In certain lighting applications, the multiple switch configuration can enable selection between different lighting distribution patterns. The electrical circuit 116 can be connected to edge-fire LEDs that emit light parallel to a substrate surface to provide uniform edge-lit illumination across a panel or diffuser, while another electrical circuit 116 can be connected to top-fire LEDs that emit light perpendicular to the substrate surface to provide directional spot lighting or focused task lighting. The user can select between these lighting modes through independent actuation of the actuator 126 and another actuator 126. Operating only the first actuator 126 activates edge-fire illumination for ambient or backlight applications, operating only the second actuator 126 activates top-fire illumination for focused reading or map light applications, and operating both actuators 126 simultaneously provides combined ambient and directional lighting. The multiple switch configuration thereby allows a single flexible printed electronic assembly 100 to accommodate multiple lighting functions without requiring separate light fixtures or control systems.

The multiple switch configuration can further provide ON/OFF control with predetermined fixed intensity levels as an alternative to variable positioning control. In such embodiments, each actuator 126 can be configured with discrete activated and deactivated positions without intermediate positioning options. The path contact 106 of each actuator 126 can connect to electrical circuits 116 that include fixed current-limiting resistors selected to produce specific predetermined brightness levels. For example, the electrical circuit 116 can include a first resistor that produces low-intensity illumination when the actuator 126 is in the activated position, while another electrical circuit 116 can include a second resistor that produces high-intensity illumination when another actuator 126 is in the activated position. The user can select off (both actuators deactivated), low intensity (first actuator activated only), high intensity (second actuator activated only), or combined intensity (both actuators activated) through discrete switching actions. This configuration eliminates the need for precise actuator positioning to achieve desired intensity levels, simplifying user operation while maintaining multiple lighting options within the integrated assembly.

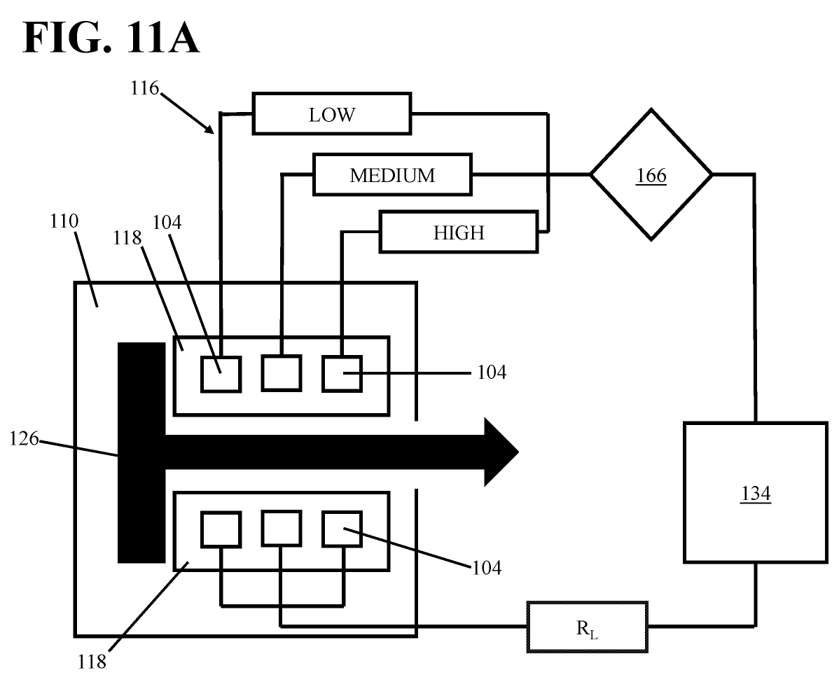

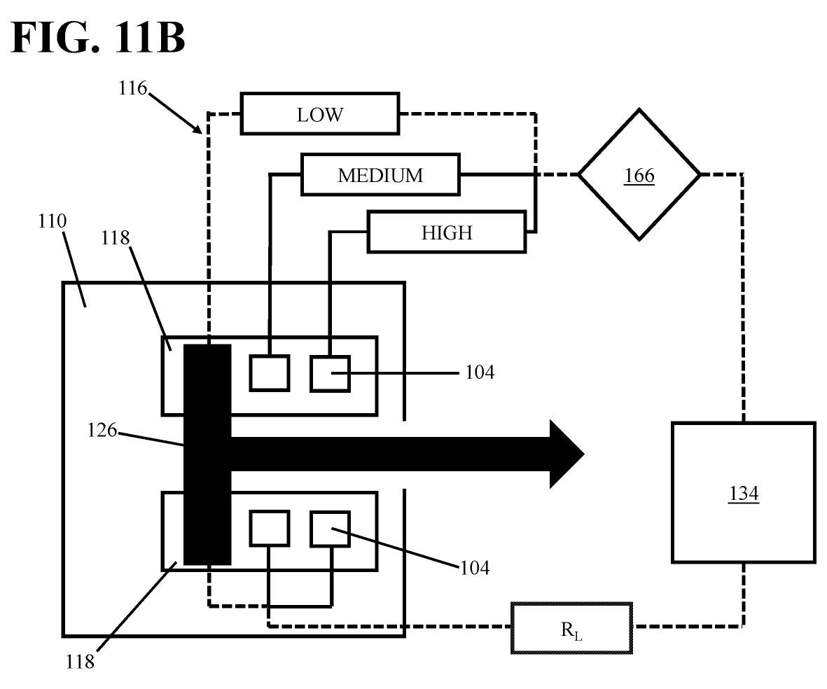

With reference to FIGS. 11A-11B, the multiple electrical circuit 116 embodiment can be used to control brightness of a display , for example an OLED display, in one application by providing the option for various brightness levels, for example, low medium, and high. The electrical circuit 116 can include three different limiting resistors, one with high resistance for dim light, one with medium resistance for moderate brightness, and one with low resistance for full brightness. The base electrical contacts 104 array can be divided into sections corresponding to off, low, medium, and high positions. Where the actuator 126 moves to the low position, the path contact 106 can connect to the high-resistance circuit producing dim light, as illustrated in FIG. 11B where the movement of electricity is depicted using dashed lines. Moving to medium can connect to the medium-resistance circuit for brighter light, and high connect can to the low-resistance circuit for maximum brightness. In this way, the flexible printed electronic assembly 100 provides adjustable brightness levels while conserving battery power.

The path contact 106 can be used in an analog configuration of the flexible printed electronic assembly 100 to provide continuously variable resistance instead of switching positions. Rather than separate metal contacts, a strip of carbon-based resistive ink can be printed in an arc or line pattern on the base portion 110, for example. The actuator 126 can carry a metal contact wiper on an underside that slides along the resistive strip as the actuator 126 moves. The resistance between the wiper and the end of the resistive strip changes continuously based on where the actuator 126 is positioned, creating a variable voltage output that corresponds to the exact position of the actuator 126.

The assembly accommodates diverse geometric configurations tailored to specific application requirements and manufacturing constraints. Contact shapes and patterns may vary from simple circular pads to elongated rectangular traces, curved arc segments for rotary applications, or complex multi-fingered configurations that enhance contact reliability through redundant connection points. Embossing profiles can be adjusted in height, diameter, and cross-sectional shape to optimize contact pressure for different substrate thicknesses and material properties, with dome heights ranging from shallow 0.5mm rises for thin flexible applications to pronounced 2mm domes for applications requiring substantial mechanical stiffness. Fold line angles and positions similarly adapt to geometric constraints, with fold lines positioned perpendicular, parallel, or diagonal to circuit traces depending on component placement and assembly workflow considerations, and fold angles ranging from standard 180-degree folds creating flat overlapping layers to acute or obtuse angles that create three-dimensional pocket geometries for specialized applications.

It should be appreciated that the foldover and embossing techniques described herein can be scaled across a broad range of physical dimensions to accommodate diverse application requirements. Miniature implementations suitable for compact wearable devices or space-constrained electronics can feature overall assembly dimensions under 10mm, for example, with individual contact pads, such as the base electrical contacts 104 and the path contact 106 measuring 1mm or less. Large-format applications for industrial controls, retail displays, or architectural lighting systems may incorporate actuator travel distances exceeding 50mm, for example, contact arrays spanning hundreds of millimeters, and embossed features several millimeters in height, with the flexible substrate construction allowing the oversized assemblies to conform to mounting surfaces while maintaining the same operating principles as the miniature version. The scalability of the flexible printed electronic assembly 100 stems from the geometric relationships between embossing depth, substrate thickness, and contact pressure remaining proportionally consistent across size ranges, allowing a single approach to serve applications varying by orders of magnitude in physical scale.

The present disclosure further provides a method 200 for operating a flexible printed electronic assembly 100, shown generally in FIG. 13. The method 200 can include providing the flexible printed electronic assembly 100 including the base electrical contacts 104 and the path contact 106 as described herein. In a step 202, the method can include placing the base electrical contacts 104 and the path contact 106 in electrical communication, whereby an electrical circuit is formed.

The present disclosure further provides a method 300 for operating a flexible printed electronic assembly 100, shown generally in FIG. 14. The method 300 can include providing the flexible printed electronic assembly 100 including the base electrical contacts 104 and the actuator 126 as the path contact 106 as described herein. In a step 302, the method can include moving the actuator 126 to place the base electrical contacts 104 and the path contact 106 in electrical communication, whereby an electrical circuit is formed.

Advantageously, the foldover and embossing configurations described herein provide electrical connections in flexible printed electronic circuits while maintaining thin conformable profiles suitable for diverse applications. The flexible substrate 102, base embossed portion 118, and the foldover embossed portion 124 can create mechanical stiffness that promotes consistent electrical performance despite the flexibility of the flexible substrate 102, reducing the need for a rigid circuit board or separate connector hardware. The ability of the flexible printed electronic assembly 100 to work in conjunction with a switch, connector, battery holder, and combinations thereof provides versatility and flexibility across applications ranging from disposable consumer products to durable electronic devices. While specific embodiments have been described in detail, those skilled in the art will recognize that variations and modifications are possible without departing from the scope of the invention as defined by the appended claims.

### Examples

The flexible printed electronic assembly 100 described herein finds application across diverse product categories and markets including, for example, illuminated product labels for wine bottles, beer bottles, and premium packaging, point-of-sale displays providing interactive product information, flexible electronics for wearable devices and medical monitoring patches, smart packaging and disposable electronics, greeting cards and promotional materials, educational toys, and temporary event badges. The conformable construction, reusable switching functionality, and simplified assembly enabled by the foldover and embossing configurations adapt to varied implementation requirements ranging from single-use disposable applications to durable reusable systems, from battery-powered portable assemblies to externally powered permanent installations, and from simple on-off switching to complex multi-mode operation with touch-sensitive controls. Certain representative examples are discussed in more detail herein to illustrate specific configurations and design considerations applicable to particular market segments.

### Example 1 - Illuminated Wine Bottle Label

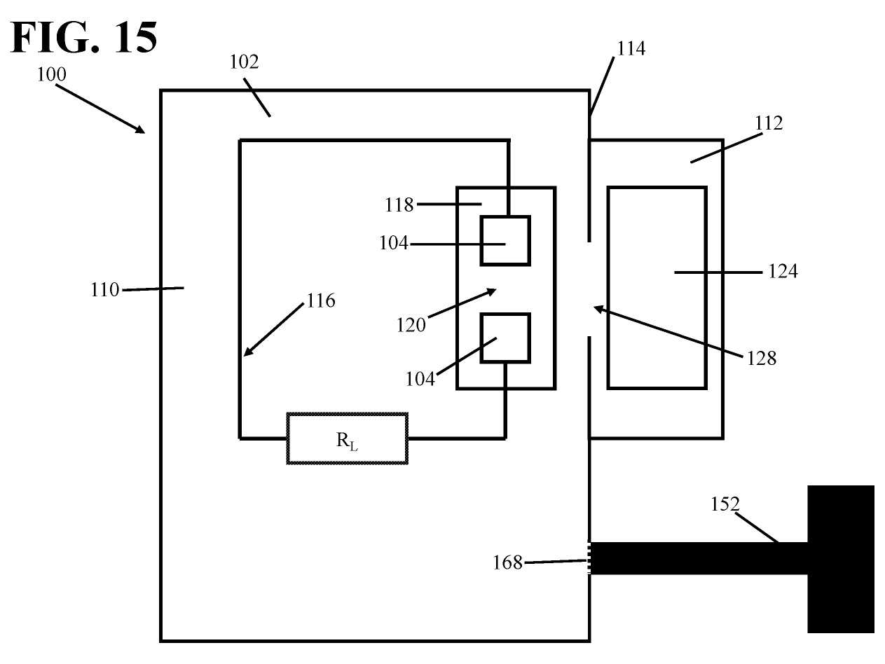

An illuminated label assembly can be configured for application to a premium wine bottle in a retail and/or hospitality environment. The flexible substrate 102 of the flexible printed electronic assembly 100 can conform to a curved sidewall surface of a standard 750ml wine bottle. Printed conductive traces forming the electrical circuit 116 on the base portion 110 can connect a battery 134 arranged in series to an OLED display element positioned to illuminate decorative graphics on the outward-facing label surface. A pull tab actuator 152 can extend from beneath an adhesive-backed decorative label layer via the opening 128 along the fold line 114, allowing a user to activate illumination by pulling the pull tab actuator 152 outward to align the path contact 106 on the underside 154 of the pull tab actuator 152 with the pair of base electrical contacts 104 on the base portion 110. The limiting resistor integrated into the electrical circuit 116 can provide approximately 2-3 hours of continuous illumination from the battery 134. When the establishment serving the beverage desires permanent illumination for the duration of customer use, a perforation 168, shown in FIG. 15, in the pull tab actuator 152 can enable tearing away a portion of the pull tab actuator 152 to maintain the electrical circuit 116 in the closed position. The conformable nature of the flexible substrate 102 can allow the flexible printed electronic assembly 100 to wrap smoothly around the bottle contour with the battery 134 positioned on the back side hidden from view, maintaining aesthetic appearance while providing functional illumination that can enhance product visibility and consumer engagement in dim bar and restaurant environments.

### Example 2 - Point-of-Sale Display with Multi-Mode Illumination

A retail point-of-sale display for premium spirits can incorporate the flexible printed electronic assembly 100 including multiple operating modes controlled through the pull tab actuator 152 configured with sequential contact positions. The base portion 110 can include a control integrated circuit that can sequence through steady-on, slow flash, and pulsing intensity modes as the user manipulates the pull tab actuator 152. Pulling the pull tab actuator 152 to a first position can supply power to the control circuit via the electrical circuit 116, while advancing the pull tab actuator 152 to a second position can provide a trigger pulse that toggles to the next illumination mode. The flexible printed electronic assembly 100 can include a battery flexible tail 140 extending from the battery system 138, terminating in a USB connector that can allow the display to operate continuously without battery 134 depletion during extended retail presentation periods. The configuration can provide flexibility for retailers to use the battery 134 for short promotional periods or external power for permanent display installations, with the multi-mode functionality offering varied visual effects that can attract customer attention while conserving power through reduced-intensity operating modes.

### Example 3 - Interactive Greeting Card

A greeting card application can incorporate the flexible printed electronic assembly 100 with the pull tab actuator 152 to control illuminated decorative elements embedded within the card construction. The flexible printed electronic assembly 100 can attach to the interior surface of a folded card stock, with an OLED display aligned with cutout windows in the card face that can reveal illuminated graphics when activated. The pull tab actuator 152 can extend through the opening 128 die-cut along the fold line 114, allowing the recipient to pull the pull tab actuator 152 outward to activate illumination and push it back to deactivate, providing reusable on-off control that can distinguish this implementation from single-use pull tab greeting cards common in the market. The flexible substrate 102 measuring less than 2mm in total thickness can allow the card to maintain a substantially flat profile suitable for standard envelope mailing, while the conformable flexible substrate 102 can accommodate folding stresses without damage to the electrical circuit 116. The retaining member 148 with the end portion 150 on the pull tab actuator 152 can militate against complete removal during normal use, ensuring the recipient does not accidentally detach the pull tab actuator 152 and disable switching functionality.

### Example 4 - Wearable Activity Monitoring Patch

A flexible health monitoring patch worn on the skin can incorporate the flexible printed electronic assembly 100 with the film connector 142 that can enable connection of sensor modules without permanent adhesive bonding. The base portion 110 adhering to the skin can include the electrical circuit 116 with printed conductive traces connecting to a wireless transmission circuit and battery 134 held in the cavity 122 formed by the foldover portion 112, with the pair of base electrical contacts 104 providing reliable electrical connection to the terminals of the battery 134. The film connector 142 configuration can include the pair of base electrical contacts 104 on the base portion 110 and the foldover embossed portion 124 on the foldover portion 112, creating the cavity 122 with opposing embossed contacts that can grip the connector flexible tail 144 of an insertable heart rate sensor module via the path contact 106 on the connector flexible tail 144. Medical personnel can insert different sensor types into the cavity 122 via the opening 128 depending on monitoring requirements, with the mechanical pressure engagement eliminating the need for conductive adhesive application that would complicate sensor replacement and increase assembly time. The conformable flexible substrate 102 can allow the patch to flex with body movement without loss of electrical contact, maintaining reliable sensor data transmission during physical activity. When the monitoring period concludes, the sensor module can be removed from the cavity 122 by pulling the connector flexible tail 144, allowing sensor sterilization and reuse with a fresh adhesive patch for subsequent patients, reducing medical waste and component costs compared to permanently bonded disposable sensor assemblies.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments can be embodied in many different forms, and that neither should be construed to limit the scope of the disclosure. In some example embodiments, well-known processes, well-known device structures, and well-known technologies are not described in detail. Equivalent changes, modifications and variations of some embodiments, materials, compositions and methods can be made within the scope of the present technology, with substantially similar results.

What is claimed is:

1. A flexible printed electronic assembly, comprising:
a flexible substrate including a base portion and a foldover portion, the base portion and the foldover portion integrally connected along a fold line, the foldover portion and the base portion defining a cavity therebetween, a printed electrical circuit disposed at least one of the base portion and the foldover portion, the base portion having a base embossed portion extending above a surface plane of the base portion and the foldover portion having a foldover embossed portion extending above a surface plane of the foldover portion;
a pair of base electrical contacts disposed on the base embossed portion of the base portion, the base electrical contacts spaced apart from each other on the base portion;
a path contact received by the cavity formed between the base portion and the foldover portion, the path contact in selective electrical communication with the pair of base electrical contacts to complete the printed electrical circuit; and
a securing member for securing the foldover portion to the base portion.

2. The flexible printed electronic assembly of claim 1, further including a display in electronic communication with the printed electrical circuit.

3. The flexible printed electronic assembly of claim 1, wherein the flexible substrate is non-electrically conductive.

4. The flexible printed electronic assembly of claim 1, wherein the printed electrical circuit is formed using at least one of screen printing, inkjet printing, and flexographic printing.

5. The flexible printed electronic assembly of claim 1, wherein the base embossed portion and the foldover embossed portion are disposed opposite one another when the foldover portion is folded along the fold line.

6. The flexible printed electronic assembly of claim 1, wherein the fold line includes an opening to permit access to the cavity.

7. The flexible printed electronic assembly of claim 6, wherein the path contact can be disposed within the cavity or removed from the cavity via the opening.

8. The flexible printed electronic assembly of claim 1, wherein the flexible substrate is pre-scored along the fold line.

9. The flexible printed electronic assembly of claim 1, wherein the pair of base electrical contacts are disposed linearly opposite one another on the base portion.

10. The flexible printed electronic assembly of claim 1, wherein the path contact is disposed on a battery disposed within the cavity.

11. The flexible printed electronic assembly of claim 10, wherein the base portion or the foldover portion includes a cutout configured to receive and position the battery within the cavity.

12. The flexible printed electronic assembly of claim 1, further comprising a connector having a connector flexible tail coupled to the path contact received into the cavity via an opening into the cavity.

13. A flexible printed electronic assembly, comprising:
a flexible substrate including a base portion and a foldover portion, the base portion and the foldover portion integrally connected along a fold line, the foldover portion and the base portion defining a cavity therebetween, a printed electrical circuit disposed on the base portion, the base portion having a base embossed portion extending above a surface plane of the base portion and the foldover portion having a foldover embossed portion extending above a surface plane of the foldover portion;
a pair of base electrical contacts disposed on the base embossed portion of the base portion, the base electrical contacts spaced apart from each other on the base portion;
a path contact received by the cavity formed between the base portion and the foldover portion, the path contact in selective electrical communication with the pair of base electrical contacts to complete the printed electrical circuit;
a securing member;
an actuator coupled to the path contact and configured for repeated movement relative to the base portion between an activated position and a deactivated position, wherein in the activated position, the path contact completes the printed electrical circuit with the pair of base electrical contacts, and in the deactivated position, the actuator interrupts the printed electrical circuit; and
a retaining member configured to maintain the actuator between the base portion and the foldover portion while permitting repeated movement between the activated position and the deactivated position.

14. The flexible printed electronic assembly of claim 13, wherein the actuator includes a pull tab actuator extending through an opening in the flexible substrate and configured for translational motion perpendicular to the base portion between the activated position and the deactivated position.

15. The flexible printed electronic assembly of claim 13, wherein the actuator includes a slider actuator configured for translational motion parallel to the base portion between the activated position and the deactivated position.

16. The flexible printed electronic assembly of claim 13, wherein the actuator includes a rotary tab actuator configured for rotational motion about a fixed attachment point between the activated position and the deactivated position.

17. The flexible printed electronic assembly of claim 16, wherein the rotary tab actuator includes a protrusion extending from the actuator that engages with the flexible substrate.

18. The flexible printed electronic assembly of claim 13, wherein the retaining member includes a ridge disposed on an end portion of the actuator, the ridge configured to abut against the foldover portion to militate against complete withdrawal of the actuator from the flexible printed electronic assembly.

19. A method of operating a flexible printed electronic assembly comprising:
providing the flexible printed electronic assembly of claim 1;
placing the pair of base electrical contacts and the path contact in electrical communication, whereby the electrical circuit is completed.

20. A method of operating a flexible printed electronic assembly comprising:
providing the flexible printed electronic assembly of claim 13;
moving the actuator to the activated position such that the pair of base electrical contacts and the path contact are placed in electrical communication, whereby the electrical circuit is completed.
